(19) United States
(12) Patent Application Publication
(10) Pub. No.: US 2025/0216606 A1
(43) Pub. Date: Jul. 3, 2025

(54) OPTICAL CIRCUIT BOARD

(71) Applicant: KYOCERA CORPORATION, Kyoto-shi, Kyoto (JP)

(72) Inventor: Shinya TOMOZAWA, Konan-shi (JP)

(73) Assignee: KYOCERA CORPORATION, Kyoto-shi, Kyoto (JP)

(21) Appl. No.: 18/852,995

(22) PCT Filed: Mar. 24, 2023
(86) PCT No.: PCT/JP2023/011874

§ 371 Date: Sep. 30, 2024

(30) Foreign Application Priority Data
Mar. 31, 2022 (JP) 2022-060159

(51) Int. Cl. G02B 6/122

(52) U.S. Cl. CPC G02B 6/122

(57) ABSTRACT

An optical circuit board according to the present disclosure includes a wiring board, a lower cladding located on the wiring board and having a first region and a second region, an optical waveguide located on the first region and including a core and an upper cladding, and a guide structure located on the second region and adjacent to the optical waveguide. The guide structure includes at least a first portion and a second portion extending adjacent to each other from an outer edge side to a center side of the wiring board in a plan view, a third portion extending from an end portion of the first portion on the center side away from the second portion, and a fourth portion extending from an end portion of the second portion on the center side away from the first portion.

### TECHNICAL FIELD

The present invention relates to an optical circuit board and an optical module using the same.

### BACKGROUND OF INVENTION

In recent years, an optical fiber capable of communicating a large amount of data at a high speed has been used in infocommunications. The optical signal is transmitted and received between the optical fiber and an optical component. Such an optical component is mounted on an optical circuit board as described in, for example, Patent Document 1.

### CITATION LIST

### Patent Literature

Patent Document 1: JP 6264832 B

### SUMMARY

### Solution to Problem

An optical circuit board according to the present disclosure includes a wiring board, a lower cladding located on the wiring board and having a first region and a second region, an optical waveguide located on the first region and including a core and an upper cladding, and a guide structure located on the second region and adjacent to the optical waveguide. The guide structure includes at least a first portion and a second portion extending adjacent to each other from the outer edge side to the center side of the wiring board in a plan view, a third portion extending from an end portion of the first portion on the center side away from the second portion, and a fourth portion extending from an end portion of the second portion on the center side away from the first portion. The third portion and the fourth portion include a first protruding portion and/or a second protruding portion. The first protruding portion is a protruding portion protruding from a side opposite to a side close to the first portion among two side edge portions of the third portion and/or a side opposite to a side close to the second portion among two side edge portions of the fourth portion in a plan view. The second protruding portion is a protruding portion protruding into the lower cladding from the third portion and/or the fourth portion in a cross-sectional view.

An optical module according to the present disclosure includes the optical circuit board, and an optical connector in contact with the guide structure and connected to the optical circuit board.

### BRIEF DESCRIPTION OF THE DRAWINGS

FIG. 1 is a plan view illustrating an optical module in which an optical component and an electronic component are mounted on an optical circuit board according to an embodiment of the present disclosure.

FIG. 2 is an enlarged explanatory view for explaining a cross section passing through the optical waveguide core in a region R1 illustrated in FIG. 1.

FIG. 3 is an enlarged explanatory view for explaining states before and after the optical waveguide and the optical connector are connected to each other in a region R2 illustrated in FIG. 2.

FIG. 4 is a plan view as seen from the direction of an arrow A illustrated in FIG. 3.

FIG. 5 is an enlarged explanatory view for explaining a region R3 illustrated in FIG. 4.

FIGS. 6A to 6E are an explanatory view for explaining various embodiments of a cross section taken along a line a-a illustrated in FIG. 5.

FIGS. 7A to 7E are an explanatory view for explaining various embodiments of a cross section taken along a line b-b illustrated in FIG. 5.

FIG. 8 is an enlarged cross-sectional view of a principal part in a state where the optical connector is connected to an optical circuit board.

### DESCRIPTION OF EMBODIMENTS

As described in Patent Document 1, in some cases, a conventional optical waveguide cannot be mounted with high accuracy due to poor formation of a connector guide disposed at an edge portion of a substrate or peeling of the connector guide. Therefore, there is a demand for an optical circuit board that can be connected to a connector with high accuracy even at an edge portion of the board.

The optical circuit board according to the present disclosure can be connected to the connector with high accuracy even at the edge portion of the board by having the configuration described in the “solution to problem” section.

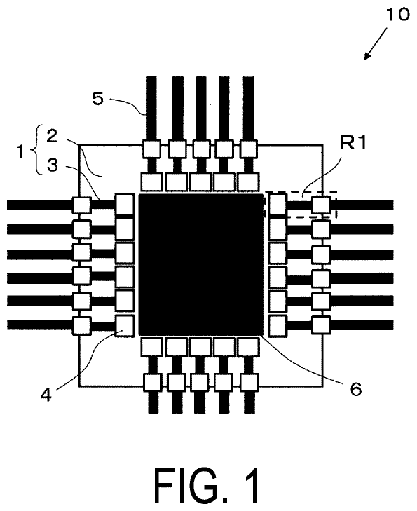

An optical circuit board according to an embodiment of the present disclosure will be described with reference to FIGS. 1 to 8. FIG. 1 is a plan view illustrating an optical module 10 in which an optical component 4 is mounted on an optical circuit board 1 according to an embodiment of the present disclosure.

The optical circuit board 1 according to an embodiment of the present disclosure includes a wiring board 2 and an optical waveguide 3. As the wiring board 2 included in the optical circuit board 1 according to the embodiment, a wiring board generally used for an optical circuit board is exemplified.

Although not specifically illustrated, the wiring board 2 includes, for example, a core substrate and build-up layers layered on both surfaces of the core substrate. The core substrate is not particularly limited as long as it is made of an insulating material. Examples of insulating materials include resins such as epoxy resin, bismaleimide-triazine resins, polyimide resins, and polyphenylene ether resins. These resins may be used in combination of two or more thereof. The core substrate usually has a through hole conductor for electrically connecting the upper and lower surfaces of the core substrate.

The core substrate may include a reinforcing material. Examples of the reinforcing material include insulating cloth materials such as glass fiber, glass nonwoven fabric, aramid nonwoven fabric, aramid fiber, and polyester fiber. Two or more kinds of reinforcing materials may be used in combination. An inorganic filler such as silica, barium sulfate, talc, clay, glass, calcium carbonate, or titanium oxide may be dispersed in the core substrate.

The build-up layer has a structure in which insulating layers and conductive layers are alternately laminated. A part of the uppermost conductive layer (the conductive layer located on the upper surface of the wiring board 2) includes a conductive layer 21a in which the optical waveguide 3 is located. The conductive layer 21a is made of, for example, Cu. Similarly to the core substrate, the insulating layer included in the build-up layer is not particularly limited as long as it is a material having an insulating property. Examples of insulating materials include resins such as epoxy resin, bismaleimide-triazine resins, polyimide resins, and polyphenylene ether resins. These resins may be used in combination of two or more thereof.

When two or more insulating layers are present in the build-up layer, the respective insulating layers may be made of the same resin or different resins. The insulating layer included in the build-up layer and the core substrate may be made of the same resin or different resins. The build-up layer usually has a via hole conductor for electrically connecting between layers.

An inorganic filler such as silica, barium sulfate, talc, clay, glass, calcium carbonate, or titanium oxide may be dispersed in the insulating layer included in the build-up layer.

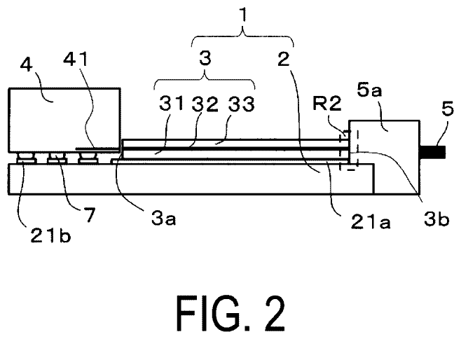

As illustrated in FIG. 2, the optical waveguide 3 included in the optical circuit board 1 according to one embodiment is located on the surface of the conductive layer 21a present on the surface of the wiring board 2. FIG. 2 is an enlarged explanatory view for explaining a cross section of a region R1 illustrated in FIG. 1. The optical waveguide 3 has a structure in which a lower cladding 31, an optical waveguide core 32, and an upper cladding 33 are layered in this order from the conductive layer 21a side.

The lower cladding 31 included in the optical waveguide 3 is located on the surface of the wiring board 2, i.e., the surface of the conductive layer 21a present on the surface of the wiring board 2. The lower cladding 31 has a first region 311 in which the optical waveguide core 32 to be described below is located and a second region 312 in which a guide structure 34 to be described below is located. The material forming the lower cladding 31 is not limited, and examples thereof include resins such as epoxy resin and silicone resin.

The upper cladding 33 included in the optical waveguide 3 is located in the first region 311. Similarly to the lower cladding 31, the upper cladding 33 is made of resins such as epoxy resin and silicone resin. The lower cladding 31 and the upper cladding 33 may be made of the same material or different materials. The lower cladding 31 and the upper cladding 33 may have the same thickness or different thicknesses. Each of the lower cladding 31 and the upper cladding 33 has a thickness of, for example, about 5 μm or more and 150 μm or less.

The optical waveguide core 32 included in the optical waveguide 3 is located in the first region 311. The optical waveguide core 32 is a portion through which light entering the optical waveguide 3 propagates. Specifically, an end surface of an optical transmission path 41 included in the optical component 4 mounted on the wiring board 2 and an end surface of the optical waveguide core 32 of the optical waveguide 3 are located so as to face each other. As illustrated in FIG. 2, the end surface of the optical waveguide 3 including the end surface of the optical waveguide core 32 facing the optical component 4 mounted on the wiring board 2 is referred to as a first end surface 3a.

At the first end surface 3a, optical signals are transmitted and received between the optical waveguide core 32 and the optical transmission path 41. The material forming the optical waveguide core 32 is not limited, and is appropriately set in consideration of, for example, transmittance of light, wavelength characteristics of propagating light, and the like. Examples of the material include resins such as an epoxy resin and a silicone resin. The optical waveguide core 32 has a thickness of, for example, about 3 μm or more and 50 μm or less.

In the optical waveguide 3, the end surface located on the side opposite to the first end surface 3a is a second end surface 3b, and includes the end surface of the lower cladding 31, the end surface of the optical waveguide core 32, and the end surface of the upper cladding 33 in the same plane. To be specific, as illustrated in FIG. 2, in the optical waveguide 3, the end surface opposed to an optical connector 5a is the second end surface 3b.

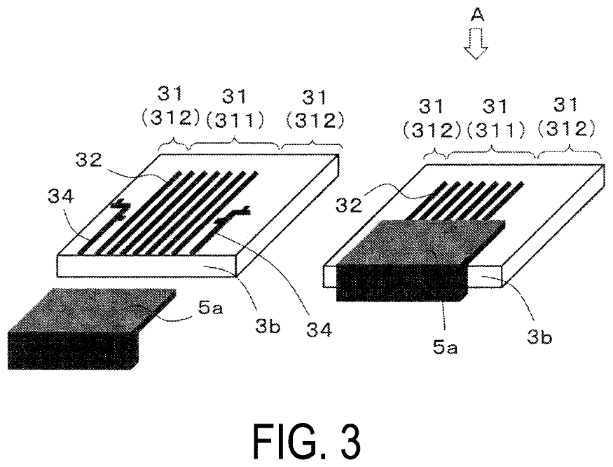

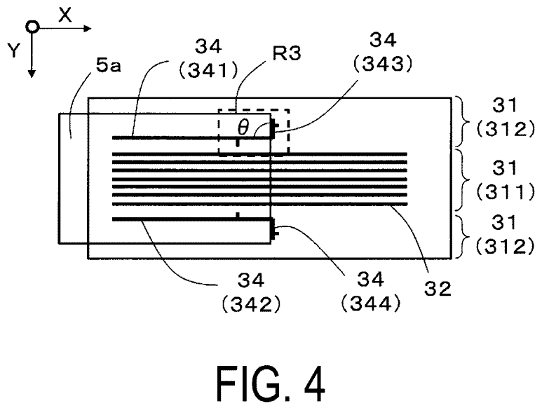

A region R2 illustrated in FIG. 2 will be described with reference to FIGS. 3 and 4. FIG. 3 is an enlarged explanatory view (perspective view) for explaining states before and after the optical waveguide 3 and the optical connector 5a are connected to each other in the region R2 illustrated in FIG. 2. FIG. 4 is a plan view seen from the direction of the arrow A illustrated in FIG. 3, and a portion covered with the optical connector 5a is described as a perspective view. For convenience of explanation, a direction parallel to the optical waveguide core 32 is defined as an X direction, and a direction perpendicular to the optical waveguide core 32 is defined as a Y direction.

As illustrated in FIGS. 3 and 4, the lower cladding 31 included in the optical waveguide 3 has the first region 311 and the second region 312. The optical waveguide core 32 and the upper cladding 33 (not illustrated for convenience of explanation) are located in the first region 311 of the lower cladding 31, and constitute the optical waveguide 3. On the other hand, the guide structure 34 is located in the second region 312 of the lower cladding 31 so as to be adjacent to the optical waveguide 3 (the first region 311 of the lower cladding 31, the optical waveguide core 32, and the upper cladding 33). For example, as illustrated in FIGS. 3 and 4, the guide structure 34 may be located on both sides of the optical waveguide 3 so as to sandwich the optical waveguide 3. The guide structure 34 is used for positioning the optical connector 5a. The material forming the guide structure 34 is not limited, and examples thereof include resins such as epoxy resin and silicone resin.

As illustrated in FIG. 4, the guide structure 34 includes at least a first portion 341 and a second portion 342 extending adjacent to each other from the outer edge side to the center side of the wiring board 2 in a plan view, a third portion 343 extending from an end portion of the first portion 341 on the center side away from the second portion 342, and a fourth portion 344 extending from an end portion of the second portion 342 on the center side away from the first portion 341. “Extending away from the second portion” means extending in a direction different from the second portion side with respect to an imaginary extension line of the first portion. “Extending away from the first portion” means extending in a direction different from the first portion side with respect to an imaginary extension line of the second portion.

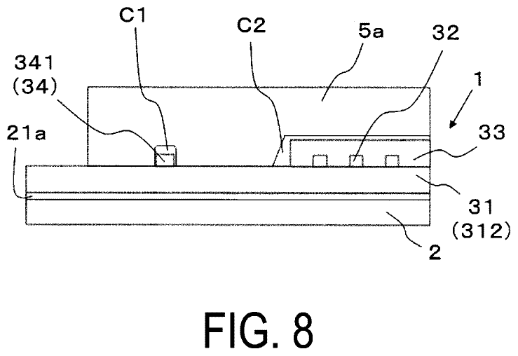

As illustrated in FIG. 8 to be described below, the optical connector 5a has, for example, a first recessed portion C1 for accommodating the guide structure 34 and a second recessed portion C2 for accommodating the upper cladding 33, on the lower cladding 31 side. The position of the optical connector 5a in the Y direction is determined by fitting the first portion 341 and the second portion 342 of the guide structure 34 into the first recessed portion C1, and the position of the optical connector 5a in the X direction is determined by bringing the side surface of the optical connector 5a into contact with the third portion 343 and the fourth portion 344 of the guide structure 34. As a result, the optical connector 5a is accurately connected to a predetermined position.

The lengths of the first portion 341 and the second portion 342 included in the guide structure 34 are appropriately set according to the size of the optical connector 5a. The widths of the first portion 341 and the second portion 342 are, for example, not less than 10 μm and not more than 50 μm. The lengths of the third portion 343 and the fourth portion 344 are appropriately set in accordance with the size of the optical connector 5a. The widths of the third portion 343 and the fourth portion 344 are, for example, not less than 10 μm and not more than 50 μm. The widths of the first portion 341 and the third portion 343 may be the same or different. The widths of the second portion 342 and the fourth portion 344 may be the same or different.

An angle θ formed by the first portion 341 and the third portion 343 is not limited, and may be approximately 90 degrees as illustrated in FIG. 4. Similarly, the angle formed by the second portion 342 and the fourth portion 344 is not limited, and may be approximately 90 degrees.

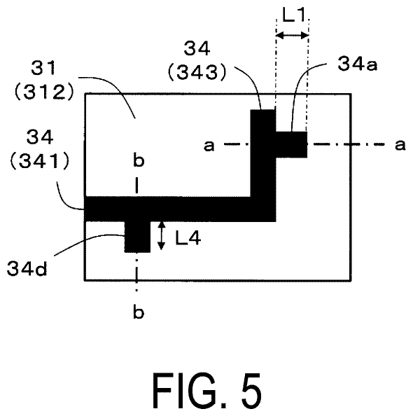

The first portion 341 and the third portion 343 will be described with reference to FIG. 5. FIG. 5 is an enlarged explanatory view for explaining a region R3 illustrated in FIG. 4. As illustrated in FIG. 5, the third portion 343 includes a first protruding portion 34a.

The first protruding portion 34a is a protruding portion protruding from one of the two side edge portions of the third portion 343 that is opposite to the side adjacent to the first portion 341 in a plan view. The first protruding portion 34a is made of the material forming the guide structure 34. The length L1 of the first protruding portion 34a, that is, the length from the side edge portion of the third portion 343 on the side opposite to the side close to the first portion 341 to the tip of the first protruding portion 34a in a plan view is, for example, 30 μm or more and 150 μm or less, and may be substantially the same as the width of the third portion 343.

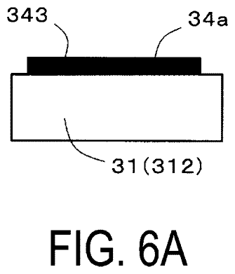

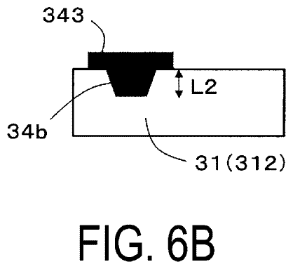

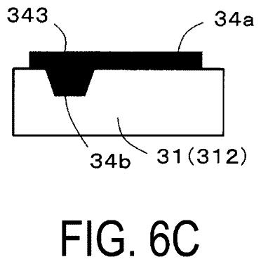

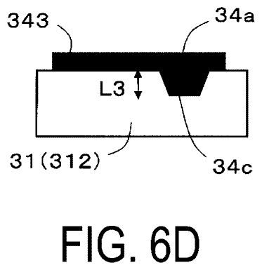

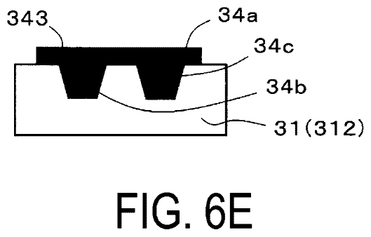

FIGS. 6A to 6E are explanatory views for explaining various embodiments of the cross section taken along the line a-a illustrated in FIG. 5. As illustrated in FIGS. 5 and 6A, the third portion 343 has a first protruding portion 34a that protrudes from one of the two side edge portions of the third portion 343 that is opposite to the side adjacent to the first portion 341. As illustrated in FIG. 6B, the third portion 343 may include a second protruding portion 34b that protrudes from the third portion 343 to the lower cladding 31 (the second region 312) in the cross-sectional view. FIG. 6B illustrates a case where the third portion 343 does not have the first protruding portion 34a. Similarly to the first protruding portion 34a, the second protruding portion 34b is made of the same material as the guide structure 34. The thickness (depth) L2 of the second protruding portion 34b is not limited, and may be, for example, about 10% or more of the thickness of the lower cladding 31.

As illustrated in FIG. 6C, both the first protruding portion 34a and the second protruding portion 34b may protrude from the third portion 343. That is, the third portion 343 includes the first protruding portion 34a and/or the second protruding portion 34b.

As illustrated in FIG. 6D, the third protruding portion 34c that protrudes from the first protruding portion 34a into the lower cladding 31 (the second region 312) in a cross-sectional view may be included. Similarly to the second protruding portion 34b, the third protruding portion 34c is made of the same material as the guide structure 34. The thickness (depth) L3 of the third protruding portion 34c is not limited, and may be, for example, about 10% or more of the thickness of the lower cladding 31. The thickness of the third protruding portion 34c may be the same as or different from the thickness of the second protruding portion 34b.

As illustrated in FIG. 6E, both the first protruding portion 34a and the second protruding portion 34b may protrude from the third portion 343, and the third protruding portion 34c may protrude from the first protruding portion 34a.

Similarly to the third portion 343, the fourth portion 344 includes the first protruding portion 34a and/or the second protruding portion 34b. The third protruding portion 34c may protrude from the first protruding portion 34a located in the fourth portion 344.

In a plan view, the direction in which the third portion 343 extends may be orthogonal to the direction in which the first protruding portion 34a protrudes. That is, the angle formed by the first protruding portion 34a located in the third portion 343 and the third portion 343 may be 90° in a plan view. In a plan view, the direction in which the fourth portion 344 extends and the direction in which the first protruding portion 34a protrudes may be orthogonal to each other. That is, the angle formed by the first protruding portion 34a located in the fourth portion 344 and the fourth portion 344 may be 90° in a plan view.

Next, as illustrated in FIG. 5, the first portion 341 may include a fourth protruding portion 34d. The fourth protruding portion 34d is a protruding portion which protrudes from the first portion 341 toward the inside of a region interposed between the first portion 341 and the second portion 342 in a plan view. The fourth protruding portion 34d is made of the material forming the guide structure 34. A length L4 of the fourth protruding portion 34d, i.e., the length from the side edge portion of the first portion 341 on the second portion 342 side to the tip thereof in a plan view, is, for example, 30 μm or more and 150 μm or less, and may be substantially the same as the width of the first portion 341.

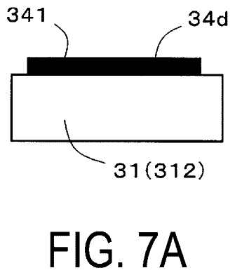

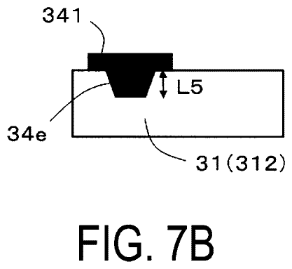

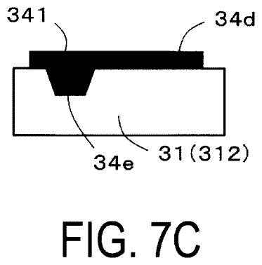

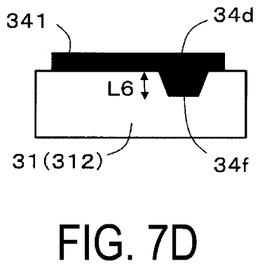

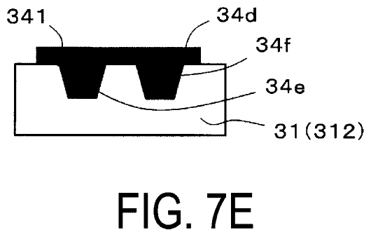

FIGS. 7A to 7E are explanatory views for explaining various embodiments of the cross section taken along the line b-b illustrated in FIG. 5. As illustrated in FIGS. 5 and 7A, the first portion 341 has the fourth protruding portion 34d protruding from the first portion 341 toward the inside of the region interposed between the first portion 341 and the second portion 342. As illustrated in FIG. 7B, the first portion 341 may include a fifth protruding portion 34e that protrudes from the first portion 341 to the lower cladding 31 (the second region 312) in a cross-sectional view. FIG. 7B illustrates a case where the first portion 341 does not have the fourth protruding portion 34d. Similarly to the fourth protruding portion 34d, the fifth protruding portion 34e is also made of the material forming the guide structure 34. The depth L5 of the fifth protruding portion 34e is not limited, and may be, for example, about 10% or more of the depth of the lower cladding 31, or may be the same depth as the second protruding portion 34b and the third protruding portion 34c.

As illustrated in FIG. 7C, both the fourth protruding portion 34d and the fifth protruding portion 34e may protrude from the first portion 341. That is, the first portion 341 may include the fourth protruding portion 34d and/or the fifth protruding portion 34e.

As illustrated in FIG. 7D, a sixth protruding portion 34f that protrudes from the fourth protruding portion 34d into the lower cladding 31 (the second region 312) in a cross-sectional view may be included. Similarly to the fifth protruding portion 34e, the sixth protruding portion 34f is also made of the material forming the guide structure 34. A thickness (depth) L6 of the sixth protruding portion 34f is not limited, and may be, for example, about 10% or more of the thickness of the lower cladding 31. The thickness of the sixth protruding portion 34f may be the same as or different from the thickness of the fifth protruding portion 34e.

As illustrated in FIG. 7E, both the fourth protruding portion 34d and the fifth protruding portion 34e may protrude from the first portion 341, and the sixth protruding portion 34f may protrude from the fourth protruding portion 34d.

Similarly to the first portion 341, the second portion 342 includes the fourth protruding portion 34d and/or the fifth protruding portion 34e. The sixth protruding portion 34f may protrude from the fourth protruding portion 34d located in the second portion 342.

In a plan view, the direction in which the first portion 341 extends may be orthogonal to the direction in which the fourth protruding portion 34d protrudes. That is, the angle formed by the first portion 341 and the fourth protruding portion 34d located in the first portion 341 may be 90° in a plan view. In a plan view, the direction in which the second portion 342 extends and the direction in which the fourth protruding portion 34d protrudes may be orthogonal to each other. That is, the angle formed by the second portion 342 and the fourth protruding portion 34d located in the second portion 342 may be 90° in a plan view.

An embodiment of a method of forming the guide structure 34 in the second region 312 of the lower cladding 31 will be described.

First, the wiring board 2 is prepared. The wiring board 2 has a mounting region of the optical component 4 and a forming region of the optical waveguide 3, which are adjacent to each other, on an upper surface thereof. The region of the wiring board 2 where the optical waveguide 3 is formed includes the conductive layer 21a, which is a part of the conductive layer located on the outermost surface (the conductive layer located on the upper surface of the wiring board 2). The mounting region of the wiring board 2 includes a pad 21b which is a part of the conductive layer located on the outermost surface. The conductive layer 21a and the pad 21b are made of metals such as copper.

Next, the lower cladding 31 is formed in a region including the formation region of the optical waveguide 3. To be more specific, a plastic layer made of epoxy resin, silicone resin, or the like is layered so as to cover the region where the optical waveguide 3 is formed. Then, exposure and development are performed to form the lower cladding 31.

Next, the optical waveguide core 32 is formed in the first region 311 of the lower cladding 31, and the guide structure 34 is formed in the second region 312 of the lower cladding 31. The optical waveguide core 32 and the guide structure 34 may be formed at the same time or separately. In order to reduce the number of processes, the guide structure 34 is preferably formed simultaneously with the optical waveguide core 32.

Before the optical waveguide core 32 and the guide structure 34 are formed, a recessed portion for forming the second protruding portion 34b, the third protruding portion 34c, the fifth protruding portion 34e, and the sixth protruding portion 34f that protrude in the second region 312 of the lower cladding 31 is formed in the second region 312 of the lower cladding 31. A method of forming the recessed portion is not limited, and examples thereof include an exposure method and a laser method. Examples of the exposure method include a method using a half-tone mask and a method of forming an extremely small-diameter hole. Examples of the laser method include a method using an excimer laser.

If necessary, a recessed portion is formed in the second region 312 of the lower cladding 31, and then materials (resins such as epoxy resin and silicone resin) for forming the optical waveguide core 32 and the guide structure 34 are applied or bonded to the first region 311 and the second region 312 of the lower cladding 31. Thereafter, the optical waveguide core 32 and the guide structure 34 are formed by performing an exposure process and a development process.

Next, the upper cladding 33 covering the optical waveguide core 32 is formed in the first region 311 of the lower cladding 31. Similarly to the lower cladding 31, the upper cladding 33 is formed by exposing and developing resins such as epoxy resin and silicone resin. The lower cladding 31 and the upper cladding 33 may be made of the same material or different materials. The lower cladding 31 and the upper cladding 33 may have the same thickness or different thicknesses.

In this manner, the guide structure 34 is formed in the second region 312 of the lower cladding 31. The optical circuit board 2 including such a guide structure 34 is used as, for example, an optical module. That is, the optical module according to the present disclosure includes the optical circuit board 1 according to the embodiment and the optical connector 5a which is in contact with the guide structure 34 and is connected to the optical circuit board 3.

The optical module 10 in which the optical component 4 and the electronic component 6 are mounted on the optical circuit board 1 according to the embodiment will be described. As illustrated in FIG. 1, the optical component 4 mounted on the optical module 10 includes the optical transmission path 41. As the optical component 4 including such an optical transmission path 41, for example, a silicon photonics device is exemplified. Examples of the electronic component 6 include an application specific integrated circuit (ASIC) and a driver IC.

As illustrated in FIG. 2, the optical component 4 is electrically connected to the pad 21b located in an optical component mounting region of the wiring board 2 via a solder 7. The pad 21b is a part of the conductive layer located on the upper surface of the wiring board 2.

A silicon photonics device will be described as an example of the optical component 4. The silicon photonics device is, for example, a type of optical component having an optical transmission path 41 in which silicon (Si) is used as a core and silicon dioxide (SiO₂) is used as a cladding. The silicon photonics device includes a Si waveguide as the optical transmission path 41, and further includes a passivation film, a light source unit, a light detection unit, and the like, which are not illustrated. As described above, the optical transmission path 41 (Si waveguide 41) is located so as to face the optical waveguide core 32 included in the optical waveguide 3 at one end of the optical waveguide 3.

For example, an electric signal from the wiring board 2 is propagated to a light source unit included in the optical component 4 (silicon photonics device) via the solder 7. The light source unit that has received the propagated electric signal emits light. The emitted optical signal is propagated to an optical fiber 5 connected via the optical connector 5a via the optical transmission path 41 (Si waveguide 41) and the optical waveguide core 32.

FIG. 8 is an enlarged cross-sectional view of a main part illustrating a state (left half) in which the connector 5a is connected to the optical circuit board 1. The connector 5a has, for example, on the lower cladding 31 side, the first recessed portion CI for accommodating the guide structure 34 and the second recessed portion C2 for accommodating the upper cladding 33. The first recessed portion C1 is substantially as wide as the guide structure 34. Thus, the connector 5a can be connected to a predetermined position of the optical circuit board 1 in the Y direction illustrated in FIG. 4.

The optical circuit board according to the present disclosure is not limited to the optical circuit board 1 according to the above-described embodiment. In the optical circuit board 1 according to the embodiment, the angle formed by the first portion 341 and the third portion 343 is approximately 90 degrees, and the angle formed by the second portion 342 and the fourth portion 344 is also approximately 90 degrees.

However, in the optical circuit board according to the present disclosure, the angle θ formed by the first portion and the third portion is not necessarily 90 degrees. For example, the angle formed by the first portion and the third portion may be an obtuse angle (e.g., more than 90 degrees and less than 180 degrees). The angle formed by the second portion and the fourth portion may also be an obtuse angle, similarly to the angle formed by the first portion and the third portion.

### BRIEF DESCRIPTION OF THE DRAWINGS

1 Optical circuit board
2 Wiring board
21a Conductive layer
21b Pad
3 Optical waveguide
31 Lower cladding
311 First region
312 Second region
32 Optical waveguide core
33 Upper cladding
34 Guide structure
341 First portion
342 Second portion
343 Third portion
344 Fourth portion
34a First protruding portion
34b Second protruding portion
34c Third protruding portion
34d Fourth protruding portion
34e Fifth protruding portion
34f Sixth protruding portion
4 Optical component
41 Optical transmission path (Silicon waveguide (Si waveguide))
5 Optical fiber
5a Optical connector
6 Electronic component
7 Solder
10 Optical module

1. An optical circuit board comprising:
a wiring board;
a lower cladding located on the wiring board and comprising a first region and a second region;
an optical waveguide located on the first region and comprising a core and an upper cladding; and
a guide structure located adjacent to the optical waveguide on the second region, wherein
the guide structure comprises at least a first portion, a second portion, a third portion, and a fourth portion, the first portion and the second portion extending adjacent to each other from an outer edge side to a center side of the wiring board in a plan view, the third portion extending from an end portion of the first portion on the center side away from the second portion, the fourth portion extending from an end portion of the second portion on the center side away from the first portion,
the third portion and the fourth portion comprise a first protruding portion and/or a second protruding portion,
the first protruding portion is a protruding portion protruding from a side opposite to a side close to the first portion among two side edge portions of the third portion and/or a side opposite to a side close to the second portion among two side edge portions of the fourth portion in a plan view, and
the second protruding portion is a protruding portion protruding into the lower cladding from the third portion and/or the fourth portion in a cross-sectional view.

2. The optical circuit board according to claim 1, wherein
the third portion and/or the fourth portion comprises a third protruding portion protruding from the first protruding portion into the lower cladding in a cross-sectional view.

3. The optical circuit board according to claim 1, wherein
in a plan view, a direction in which the third portion extends and a direction in which the first protruding portion protrudes are orthogonal to each other, and a direction in which the fourth portion extends and the direction in which the first protruding portion protrudes are orthogonal to each other.

4. The optical circuit board according to claim 1, wherein
the first portion and the second portion comprise a fourth protruding portion and/or a fifth protruding portion,
the fourth protruding portion is a protruding portion protruding from the first portion and/or the second portion toward a region interposed between the first portion and the second portion in a plan view, and
the fifth protruding portion is a protruding portion protruding into the lower cladding from the first portion and/or the second portion in a cross-sectional view.

5. The optical circuit board according to claim 4, wherein
the first portion and/or the second portion comprises a sixth protruding portion protruding from the fourth protruding portion into the lower cladding in a cross-sectional view.

6. The optical circuit board according to claim 1, wherein
the guide structure is located on both sides of the optical waveguide sandwiching the optical waveguide.

7. An optical module comprising:
the optical circuit board according to claim 1; and
an optical connector in contact with the guide structure and connected to the optical circuit board.
